(19) United States
(12) Patent Application Publication
(10) Pub. No.: US 2026/0045910 A1
(43) Pub. Date: Feb. 12, 2026

(54) DUTY CYCLE CORRECTION FOR CRYSTAL DRIVER

(71) Applicant: Microchip Technology Incorporated, Chandler, AZ (US)

(72) Inventors: Tom Parkinson, Oak Point, TX (US); Mark L. Thrower, Carrollton, TX (US); Mike Willingham, Frisco, TX (US)

(21) Appl. No.: 18/939,352

(22) Filed: Nov. 6, 2024

Related U.S. Application Data
(60) Provisional application No. 63/681,087, filed on Aug. 8, 2024.

(51) Int. Cl. H03B 5/36; H03K 3/017; H03K 5/00; H03L 7/099

(52) U.S. Cl. CPC H03B 5/36; H03K 3/017; H03K 5/00006; H03L 7/099

(57) ABSTRACT

A method to generate a crystal oscillator clock having a duty cycle via a first stage of a clock circuit, double the crystal oscillator clock and inputting the doubled crystal oscillator clock into a phased-locked loop, feed back a phase-locked loop feedback clock, measure a difference in delay between a first edge of the doubled crystal oscillator clock relative to the phase-locked loop feedback clock and a second edge of the doubled crystal oscillator clock relative to the phase-locked loop feedback clock, and adjust the duty cycle of the crystal oscillator clock based on the difference in delay. A device having a detection circuit to measure a difference in delay between first and second edges of a doubled crystal oscillator clock output relative to a phase-locked loop feedback clock, and a controller to adjust the duty cycle of the clock output based on the difference in delay.

### RELATED PATENT APPLICATION

This application claims priority to commonly owned U.S. Provisional Ser. No. 63/681,087 filed Aug. 8, 2024, the entire contents of which are hereby incorporated by reference for all purposes.

### TECHNICAL FIELD

The present disclosure relates to duty cycle clock generation, in particular, duty cycle clock correction for doubled clocks.

### BACKGROUND

In low noise clock generation products we typically create a clock with a crystal oscillator driver which then drives into a phase-locked-loop (PLL) which creates a low noise, high frequency clock which can be divided down into a desired family of output frequencies. Noise performance in these products may be improved with higher frequency references, but inexpensive fundamental crystals typically top out around 50-60 MHz. To improve noise of these crystals, these reference frequencies may be doubled by creating pulses on both edges of the crystal driver output. A problem arises if the input clock isn't 50% duty cycle, the doubled clock may have considerable cycle-to-cycle jitter, which may show up as a reference spur and prevent use of gain boost in the charge pump (which also helps improve noise performance). Prior methods of duty cycle correction have increased noise in the reference clock by more than what was gained later on with the doubled clock.

Previously, duty cycle correction has been done using additional logic, added after the crystal amplifier, to control the delays of the rising and falling edge clocks independently of each other. These circuits may have corrected the duty cycle of the input clock before doubling, but the additional circuitry in the clock path also added noise into the clock that negated the benefit of being able to double the input clock.

There is a need for a duty cycle correction that does not add more noise in the reference clock than what is gained with a doubled clock.

### SUMMARY OF THE INVENTION

According to an aspect, there is provided a method comprising: generating a crystal oscillator clock having a duty cycle via a first stage of a clock circuit; doubling the crystal oscillator clock and inputting the doubled crystal oscillator clock into a phased-locked loop; feeding back a phase-locked loop feedback clock; measuring a difference in delay between a first edge of the doubled crystal oscillator clock relative to the phase-locked loop feedback clock and a second edge of the doubled crystal oscillator clock relative to the phase-locked loop feedback clock; adjusting the duty cycle of the crystal oscillator clock based on the difference in delay.

An aspect provides a method as in the preceding paragraph, wherein adjusting the duty cycle of the crystal oscillator clock comprises adjusting the first stage of the clock circuit.

An aspect provides a method as in one of the preceding two paragraphs, wherein adjusting the first stage of the clock circuit comprises changing a threshold of a first stage amplifier.

An aspect provides a method as in one of the preceding three paragraphs, wherein adjusting the first stage of the clock circuit comprises programming a strength of a crystal driver amplifier.

An aspect provides a method as in one of the preceding four paragraphs, wherein programming the strength of a crystal driver amplifier comprises programming a P-channel driver strength and a N-channel driver strength independently.

An aspect provides a method as in one of the preceding five paragraphs, wherein adjusting the first stage of the clock circuit comprises independently enabling and disabling P-channel and N-channel devices of a plurality of amplifier stages, wherein enabling more N-channel devices than P-channel devices lowers a threshold of a first stage amplifier, wherein enabling more P-channel devices than N-channel devices raises a threshold of the first stage amplifier.

An aspect provides a method as in one of the preceding six paragraphs, wherein adjusting the duty cycle of the crystal oscillator clock comprises adjusting a second stage of the clock circuit.

An aspect provides a method as in one of the preceding seven paragraphs, wherein adjusting the second stage of the clock circuit comprises independently setting a P-channel hysteresis and an N-channel hysteresis of a Schmitt trigger.

An aspect provides a method as in one of the preceding eight paragraphs, wherein adjusting the second stage of the clock output comprises: providing a Schmitt trigger amplifier that raises a low-to-high input threshold to adjust the duty cycle of the crystal oscillator clock; providing a Schmitt trigger attenuator that lowers a high-to-low input threshold to adjust the duty cycle of the crystal oscillator clock; independently enabling sections of the Schmitt trigger amplifier to adjust the low-to-high input threshold to adjust the duty cycle of the crystal oscillator clock; and independently enabling sections of a Schmitt trigger attenuator to adjust the high-to-low input threshold to adjust the duty cycle of the crystal oscillator clock.

An aspect provides a method as in one of the preceding nine paragraphs, wherein adjusting the duty cycle of the crystal oscillator clock comprises: adjusting the first stage of the clock circuit to make a first adjustment; and adjusting a second stage of the clock circuit to make a second adjustment, wherein the first adjustment is larger than the second adjustment.

According to an aspect, there is provided a detection circuit to measure a difference in delay between a first edge of the doubled crystal oscillator clock relative to a phase-locked loop feedback clock and a second edge of the doubled crystal oscillator clock relative to the phase-locked loop feedback clock; and a controller to adjust the duty cycle of the crystal oscillator clock based on the difference in delay.

An aspect provides a device as in the preceding paragraphs, wherein the detection circuit is to: shut off the second edge of the doubled crystal oscillator clock; and measure the first delay between the first edge of the doubled crystal oscillator clock and the phase-locked loop feedback clock

An aspect provides a device as in one of the preceding two paragraphs, wherein the first edge of the doubled crystal oscillator clock is a rising edge, wherein the second edge of the doubled crystal oscillator clock is a falling edge; wherein the controller is to: adjust a first stage of a clock circuit to make a first adjustment based on the inferred duty cycle; and adjust a second stage of the clock circuit to make a second adjustment based on the inferred duty cycle, wherein the first adjustment is larger than the second adjustment.

An aspect provides a device as in one of the preceding three paragraphs, wherein the controller is to adjust a first stage of a clock circuit by programming a strength of a crystal driver amplifier by independently enabling or disabling P-channel and N-channel devices of a plurality of amplifier stages, wherein more enabled N-channel devices than P-channel devices lowers a threshold of a first stage amplifier, and wherein more enabled P-channel devices than N-channel devices raises a threshold of a first stage amplifier.

An aspect provides a device as in one of the preceding four paragraphs, wherein the controller is to adjust the duty cycle of the clock output by adjusting a second stage of a clock circuit by: independently enabling sections of a Schmitt trigger amplifier to adjust a low-to-high input threshold to adjust the duty cycle of the crystal oscillator clock; and independently enabling sections of a Schmitt trigger attenuator to adjust a high-to-low input threshold to adjust the duty cycle of the crystal oscillator clock.

According to an aspect, there is provided a system comprising: a crystal oscillator circuit to generate a crystal oscillator clock having a duty cycle; an adjustment circuit to adjust the duty cycle; a clock doubling circuit to double the crystal oscillator clock; a phase-locked loop circuit to input a doubled crystal oscillator clock and output a phase-locked loop feedback clock; a detection circuit to measure a difference in delay between a first edge of the doubled crystal oscillator clock relative to the phase-locked loop feedback clock and a second edge of the doubled crystal oscillator clock relative to the phase-locked loop feedback clock; and a controller of the adjustment circuit to adjust the duty cycle of the crystal oscillator clock based on the difference in delay.

An aspect provides a system as in the preceding paragraph, wherein the detection circuit is to: shut off an edge of the doubled crystal oscillator clock; and measure a delay between a non-shut-off edge of the doubled crystal oscillator clock and a phase-locked loop feedback clock.

An aspect provides a system as in one of the preceding two paragraphs, wherein the detection circuit is to: measure a first delay between a rising edge of the doubled crystal oscillator clock and a phase-locked loop feedback clock; measure a second delay between a falling edge of the doubled crystal oscillator clock and the phase-locked loop feedback clock; and determine an inferred duty cycle of the clock output from a difference between the first delay and the second delay; wherein the controller is to: adjust the first stage of the clock circuit to make a first adjustment based on the inferred duty cycle; and adjust the second stage of the clock circuit to make a second adjustment based on the inferred duty cycle, wherein the first adjustment is larger than the second adjustment.

An aspect provides a system as in one of the preceding three paragraphs, wherein the controller is to adjust the first stage of the clock circuit by programming a strength of a crystal driver amplifier by independently enabling or disabling P-channel and N-channel devices of a plurality of amplifier stages, wherein more enabled N-channel devices than P-channel devices lowers a threshold of a first stage amplifier, and wherein more enabled P-channel devices than N-channel devices raises a threshold of the first stage amplifier.

An aspect provides a system as in one of the preceding four paragraphs, wherein the controller is to adjust the duty cycle of the crystal oscillator clock by adjusting the second stage of the clock circuit by: independently enabling sections of a Schmitt trigger amplifier to adjust a low-to-high input threshold to adjust the duty cycle of the crystal oscillator clock; and independently enabling sections of a Schmitt trigger attenuator to adjust a high-to-low input threshold to adjust the duty cycle of the crystal oscillator clock.

### BRIEF DESCRIPTION OF THE DRAWINGS

The figures illustrate examples of a Pierce crystal oscillator driver that uses a duty cycle correction that does not add more noise in the crystal oscillator clock (reference clock) than what is gained with a doubled clock, which allows simple clock doubling of an output clock with low cycle-to-cycle jitter.

FIG. 1 shows a circuit diagram of a Pierce crystal oscillator driver allowing simple clock doubling of output clock with low cycle-to-cycle jitter.

FIG. 2 shows a circuit diagram for a programmable first stage amplifier.

FIG. 3 shows a circuit diagram of a Schmitt trigger of the second stage of the clock path.

FIG. 4 shows a timing diagram for the input clock sine wave of the crystal driver.

FIG. 5 shows a timing diagram for a duty cycle measurement methodology.

FIG. 6 shows a flow chart for a method.

FIG. 7 shows a block diagram for a device circuit.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a low additive noise duty cycle correction circuit for a Pierce crystal oscillator driver that does not add more noise in the reference clock than what is gained with a doubled clock, which allows simple clock doubling of output clock with low cycle-to-cycle jitter.

A duty cycle of a crystal oscillator clock may be adjusted. The adjustment may be based on measuring the cycle-to-cycle jitter of the doubled crystal oscillator clock. The non-doubled clock is a reference clock, or the crystal oscillator clock. The cycle-to-cycle jitter on the doubled crystal oscillator clock may be determined by measuring the difference in delay between the two edges of the doubled crystal oscillator clock verses edges of a phase-locked loop feedback clock.

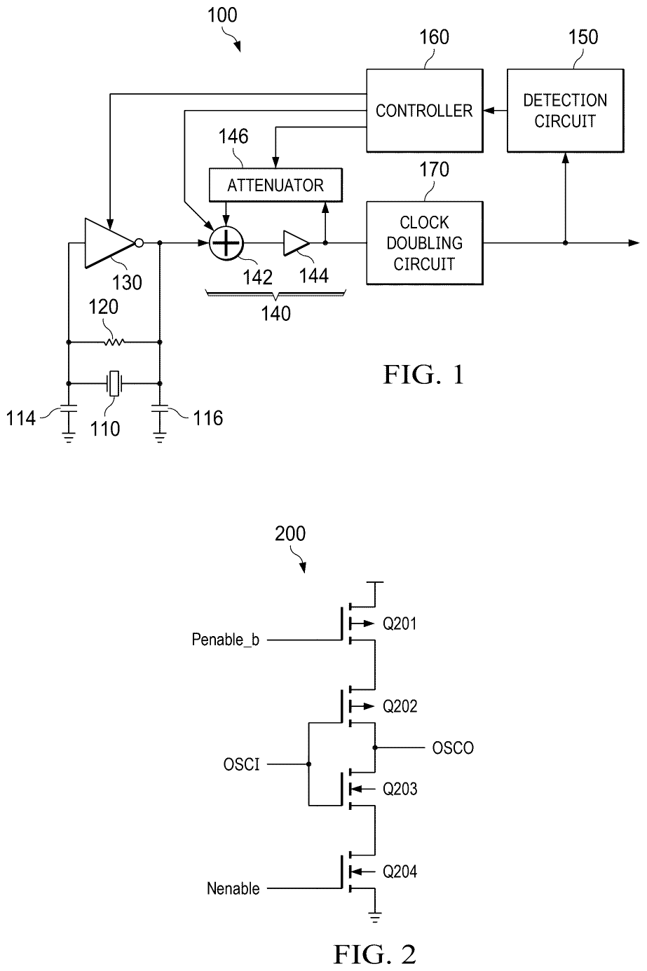

FIG. 1 shows a circuit diagram of a Pierce crystal oscillator driver 100 allowing simple clock doubling of a crystal oscillator clock with low cycle-to-cycle jitter. The Pierce crystal oscillator driver 100 has several stages. The first stage comprises a crystal oscillator 110, a first stage resistor 120, and a first stage amplifier 130, wherein these three components are connected in parallel. Opposite sides of the circuit have a capacitor 114 and 116 connected to ground. The second stage comprises a Schmitt trigger 140, wherein the Schmitt trigger 140 has an adder 142, a second stage amplifier 144, and an attenuator 146 acting as a comparator. The Schmitt trigger 140 is a positive feedback circuit in which the output signal from the second stage amplifier 144 is fed through the attenuator 146 back into the input by the adder 142 to cause the second stage amplifier 144 to switch rapidly from one saturated state to the other when the input crosses a threshold. The third stage comprises a clock doubling circuit 170 to double the crystal oscillator clock. The fourth stage comprises a detection circuit 150 that can measure the delays between a copy of the doubled crystal oscillator clock and a copy of a phase-locked loop feedback clock. The measured delay data may be fed to a controller 160, which then provides control signals to the first stage amplifier 130 and the adder 142/attenuator 146 of the second stage.

The first stage amplifier 130 may be a programmable strength crystal driver amplifier where the P-channel driver and N-channel driver strengths can be set independently of each other. The second stage Schmitt trigger 140 may be such that the P-channel hysteresis and N-channel hysteresis are independently settable. The third stage detection circuit 150 may measure the cycle-to-cycle jitter of a doubled crystal oscillator clock and the controller 160 may determine adjustments to be made to the first stage amplifier 130 and the second stage Schmitt trigger 140 to reduce cycle-to-cycle jitter. Adjusting the P-channel/N-channel ratio in the first stage amplifier 130 changes the threshold of the amplifier. Given that the crystal oscillator clock is a sine wave (thanks to the high-Q oscillator crystal 110), changing the threshold of the first stage amplifier 130 can make reasonably large adjustments to the duty cycle of the crystal oscillator clock. Adjusting the P-channel/N-channel hysteresis also affects the threshold of the Schmitt trigger second stage. Because the clock has faster edge rates at this stage, these adjustments make smaller changes to the duty cycle of the crystal oscillator clock and can be considered fine tune adjustments, whereas the amplifier adjustments are coarse tune.

An aspect provides that the duty cycle correction may be done by making minor modifications to existing clock stages, rather than by adding new stages (and new noise sources) into the clock path. Simulations show that the larger duty cycle corrections do increase the noise output of the amplifier, but the increase is small. The benefits of the clock doubler may outweigh an increase in noise in the two stages. Simulations have shown an ability to take the 2+% variations in duty cycle (approximately) that comes out of the crystal amplifier and reduce them to around a 0.2% variation in duty cycle. This may reduce the reference spurs caused by the doubled clock and enable gain boost inside the charge pump while using a doubled clock.

The first stage of this clock path may be a basic Pierce crystal amplifier driver, which may be a large inverter that is biased as a first stage amplifier 130 by a first stage resistor 120. The first stage amplifier 130 is split into four binary weighted stages which allow a “drive strength” setting of 1 to 15 (with 0 being off). The first stage amplifier 130 is controlled by control logic of the controller 160 to allow each stage of the first stage amplifier 130 to have its P-channel and N-channel devices independently enabled. In this way, the first stage amplifier 130 itself isn't modified, but it is allowed to be used in a way to control the ratio of P-channel and N-channel devices. Having more N-channel than P-channel devices will lower the threshold of the first stage amplifier 130 which will increase the duty cycle. Conversely, having more P-channel than N-channel devices enabled will raise the threshold and decrease the duty cycle of the output clock. The first stage further comprises a clock doubling circuit 170 to double the clock output.

FIG. 2 shows a circuit diagram for a programmable first stage amplifier. The programmable first stage amplifier 200 comprises four metal-oxide semiconductor field-effect transistors (MOSFET P/N enable) Q201, Q202, Q203, and Q204 connected in series. MOSFET Q201 is P enabled by Penable_b. Both MOSFET Q202 and Q203 are enabled by OSCI. MOSFET Q204 is N enabled by Nenable. A clock output is provided at OSCO. These stages (as many as 30 stages) may be connected in parallel in groups of 3, 4, 8, 16, without limitation. The P/N devices may be enabled together for gain of 1-15 (binary weighting). A digital change to the amplifier may enable P/N devices independently. For example, MOSFETs Q201, Q202, Q203, and Q204 may be independently enabled for P-channel or N-channel to program the threshold and the duty cycle.

Referring again to FIG. 1, the second stage of this clock path is a Schmitt trigger 140. This Schmitt trigger 140 may use two devices, the second stage amplifier 144 that raises the low to high input threshold and the attenuator 146 that lowers the high to low input threshold, creating hysteresis. Both the second stage amplifier 144 and the attenuator 146 are split into four separately enablable sections, allowing some variations in how much of each type of threshold adjustment is enabled. This allows for finer control of the duty cycle adjustment than changes to the first stage amplifier 130 settings. These fine tune adjustments are made to be smaller steps than the coarse tune (first stage amplifier 130 adjustments), but the range of these steps may cover the size of one of the coarse tune steps.

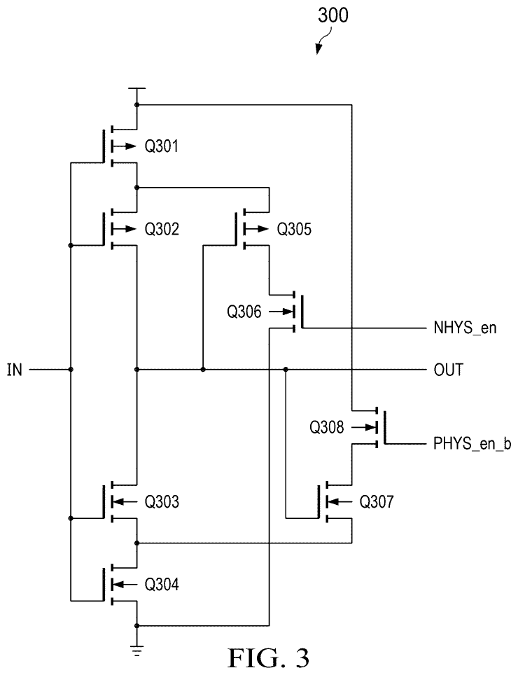

FIG. 3 shows a circuit diagram of a Schmitt trigger of the second stage of the clock path. The Schmitt trigger 300 comprises eight metal-oxide semiconductor field-effect transistors (MOSFET P/N enable) Q301, Q302, Q303, Q304, Q305, Q306, Q307, and Q308. The Schmitt trigger 300 with hysteresis that may be disabled by the gate of MOSFET Q306 via NHYS_en and the gate of MOSFET Q308 via PHYS_en_b. The hysteresis may be broken into four stages on both P/N devices to make them independently enabled. The Schmitt trigger 300 may shift the threshold of either edge of a stage either up or down to make smaller changes (relative to the changes made to the programmable first stage amplifier) to the duty cycle of the crystal oscillator clock. The Schmitt trigger 300 may be the fine tune circuit for duty cycle correction, having an accuracy of better than 0.2%.

The third stage of this clock path is a detection circuit 150. The doubled clock is fed to the detection circuit 150 that measures the delays between a copy of the doubled crystal oscillator clock and a copy of the phase-locked loop feedback clock. Each edge of the doubled crystal oscillator clock can be shut off, one at a time, and the delay between a given edge and an edge of the phase-locked loop feedback clock is measured. The difference between the delays on the rising edge pulse vs. the falling edge pulse of the doubled crystal oscillator clock can be used to infer the duty cycle of the crystal oscillator clock. This knowledge can be used to adjust the coarse settings, then fine tune settings to get closer to 50% duty cycle.

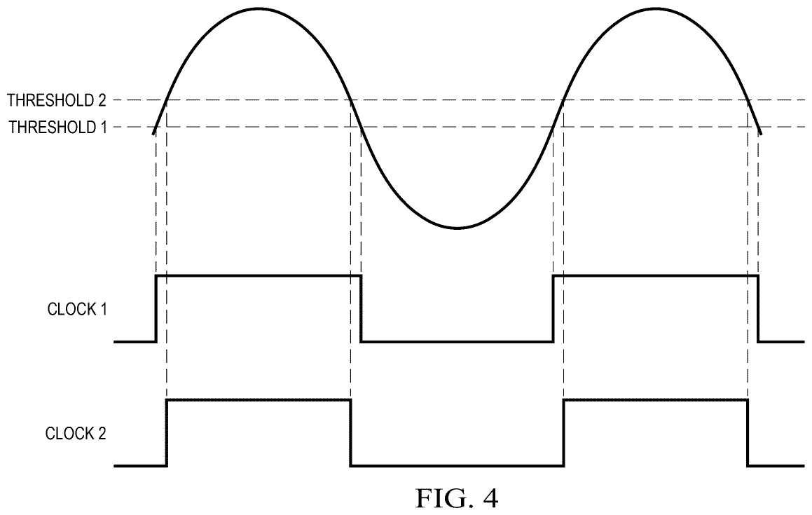

FIG. 4 shows a timing diagram for the crystal oscillator clock sine wave of the crystal driver. The first stage amplifier 200 (see FIG. 2) may be programmed between threshold 1 and threshold 2. When the first stage amplifier 200 is controlled to have threshold 1, then Clock 1 is produced. When the first stage amplifier 200 is controlled to have threshold 2, then Clock 2 is produced. Changes to the sampling point of the inverter may have a large impact on the duty cycle of the clock output. The first stage amplifier 200 may provide a range sufficient for the duty cycle error in a crystal driver mode. The first stage amplifier 200 may provide coarse tuning of the duty cycle adjustment and the Schmitt trigger 300 may provide fine tuning of the duty cycle adjustment.

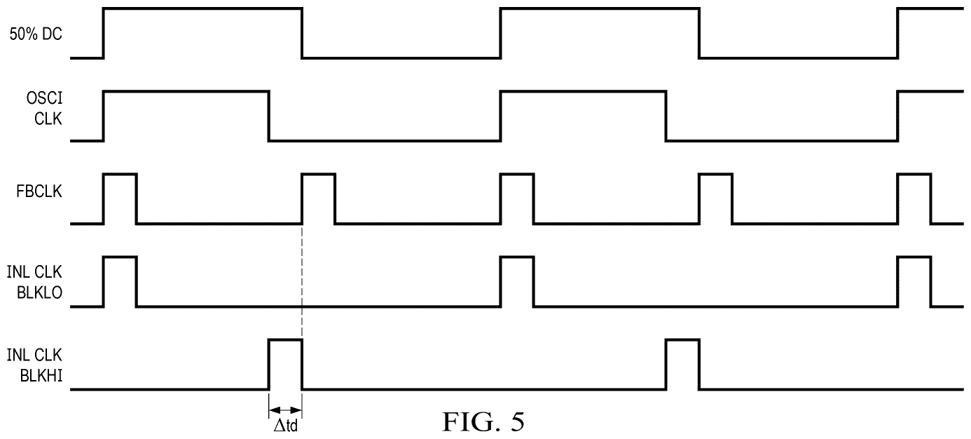

FIG. 5 shows a timing diagram for a duty cycle measurement methodology. The methodology uses a doubled crystal oscillator clock, wherein duty cycle correction may be needed in doubled clock mode. One edge of the doubled crystal oscillator clock INL CLK DLKHI is blocked in the detector by INL CLK BLKLO, which lines up the edge with a phase-locked loop feedback clock FBCLK. An opposite edge of the doubled crystal oscillator clock INL CLK DLKHI is blocked and a delay is measured to infer a duty cycle error. The delay of the other edge of the doubled crystal oscillator clock may be measured by a similar methodology.

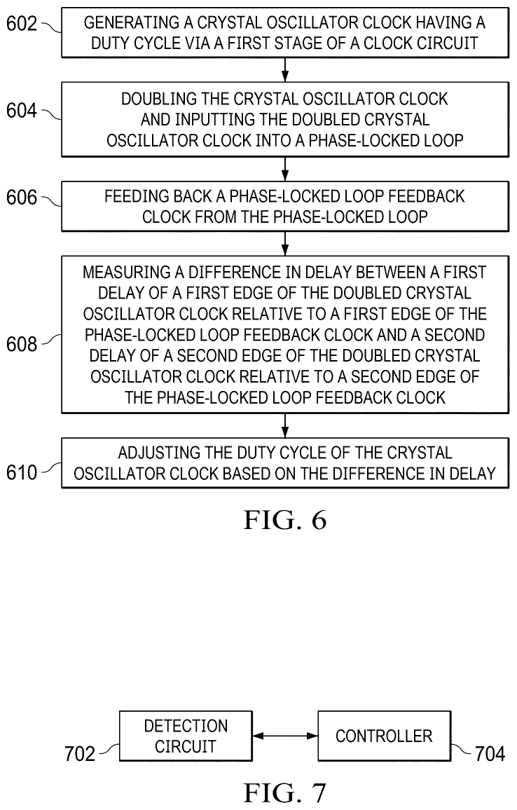

FIG. 6 shows a flow chart for a method. A crystal oscillator clock is generated 602 having a duty cycle via a first stage of a clock circuit. The crystal oscillator clock is doubled 604 and input into a phase-locked loop. A phase-locked loop feedback clock is fed back 606 from the phase-locked loop. A difference in delay is measured 608 between a first delay of a first edge of the doubled crystal oscillator clock relative to a first edge of the phase-locked loop feedback clock and a second delay of a second edge of the doubled crystal oscillator clock relative to a second edge of the phase-locked loop feedback clock. The duty cycle of the crystal oscillator clock is adjusted 610 based on the difference in delay.

FIG. 7 shows a block diagram for a device circuit. The circuit has a detection circuit 702 to measure a difference in delay between a first delay of a first edge of the doubled crystal oscillator clock relative to a first edge of a phase-locked loop feedback clock and a second delay of a second edge of the doubled crystal oscillator clock relative to a second edge of the phase-locked loop feedback clock. The circuit also has a controller 704 to adjust the duty cycle of the crystal oscillator clock based on the difference in delay.

Although examples have been described above, other variations and examples may be made from this disclosure without departing from the spirit and scope of these disclosed examples.

1. A method comprising:
generating a crystal oscillator clock having a duty cycle via a first stage of a clock circuit;
doubling the crystal oscillator clock and inputting the doubled crystal oscillator clock into a phase-locked loop;
feeding back a phase-locked loop feedback clock from the phase-locked loop;
measuring a difference in delay between a first edge of the doubled crystal oscillator clock relative to the phase-locked loop feedback clock and a second edge of the doubled crystal oscillator clock relative to the phase-locked loop feedback clock;
adjusting the duty cycle of the crystal oscillator clock based on the difference in delay.

2. The method as in claim 1, wherein adjusting the duty cycle of the crystal oscillator clock comprises adjusting the first stage of the clock circuit.

3. The method as in claim 2, wherein adjusting the first stage of the clock circuit comprises changing a threshold of a first stage amplifier.

4. The method as in claim 2, wherein adjusting the first stage of the clock circuit comprises programming a strength of a crystal driver amplifier.

5. The method as in claim 4, wherein programming the strength of a crystal driver amplifier comprises programming a P-channel driver strength and programming a N-channel driver strength.

6. The method as in claim 2, wherein adjusting the first stage of the clock circuit comprises independently enabling and disabling P-channel and N-channel devices of a plurality of amplifier stages, wherein enabling more N-channel devices than P-channel devices lowers a threshold of a first stage amplifier, wherein enabling more P-channel devices than N-channel devices raises a threshold of the first stage amplifier.

7. The method as in claim 1, wherein adjusting the duty cycle of the crystal oscillator clock comprises adjusting a second stage of the clock circuit.

8. The method as in claim 7, wherein adjusting the second stage of the clock circuit comprises independently setting a P-channel hysteresis and an N-channel hysteresis of a Schmitt trigger.

9. The method as in claim 7, wherein adjusting the second stage of the crystal oscillator circuit comprises:
providing a Schmitt trigger amplifier that raises a low-to-high input threshold to adjust the duty cycle of the crystal oscillator clock;
providing a Schmitt trigger attenuator that lowers a high-to-low input threshold to adjust the duty cycle of the crystal oscillator clock;
independently enabling sections of the Schmitt trigger amplifier to adjust the low-to-high input threshold to adjust the duty cycle of the crystal oscillator clock; and
independently enabling sections of a Schmitt trigger attenuator to adjust the high-to-low input threshold to adjust the duty cycle of the crystal oscillator clock.

10. The method as in claim 1, wherein adjusting the duty cycle of the crystal oscillator clock comprises:
adjusting the first stage of the clock circuit to make a first adjustment; and
adjusting a second stage of the clock circuit to make a second adjustment,
wherein the first adjustment is larger than the second adjustment.

11. A device comprising:
a detection circuit to measure a difference in delay between a first edge of the doubled crystal oscillator clock relative to a phase-locked loop feedback clock and a second edge of the doubled crystal oscillator clock relative to the phase-locked loop feedback clock; and
a controller to adjust the duty cycle of the crystal oscillator clock based on the difference in delay.

12. The device as in claim 11, wherein the detection circuit is to:
shut off the second edge of the doubled crystal oscillator clock; and
measure the first delay between the first edge of the doubled crystal oscillator clock and the phase-locked loop feedback clock.

13. The device as in claim 11,
wherein the first edge of the doubled crystal oscillator clock is a rising edge,
wherein the second edge of the doubled crystal oscillator clock is a falling edge,
wherein the controller is to:
adjust a first stage of a clock circuit to make a first adjustment based on the inferred duty cycle; and
adjust a second stage of the clock circuit to make a second adjustment based on the inferred duty cycle,
wherein the first adjustment is larger than the second adjustment.

14. The device as in claim 11, wherein the controller is to adjust a first stage of a clock circuit by programming a strength of a crystal driver amplifier by independently enabling or disabling P-channel and N-channel devices of a plurality of amplifier stages, wherein more enabled N-channel devices than P-channel devices lowers a threshold of a first stage amplifier, and wherein more enabled P-channel devices than N-channel devices raises a threshold of a first stage amplifier.

15. The device as in claim 11, wherein the controller is to adjust the duty cycle of the crystal oscillator clock by adjusting a second stage of a clock circuit by:
independently enabling sections of a Schmitt trigger amplifier to adjust a low-to-high input threshold to adjust the duty cycle of the crystal oscillator clock; and
independently enabling sections of a Schmitt trigger attenuator to adjust a high-to-low input threshold to adjust the duty cycle of the crystal oscillator clock.

16. A system comprising:
a crystal oscillator circuit to generate a crystal oscillator clock having a duty cycle;
an adjustment circuit to adjust the duty cycle;
a clock doubling circuit to double the crystal oscillator clock;
a phase-locked loop circuit to input a doubled crystal oscillator clock and output a phase-locked loop feedback clock;
a detection circuit to measure a difference in delay between a first edge of the doubled crystal oscillator clock relative to the phase-locked loop feedback clock and a second edge of the doubled crystal oscillator clock relative to the phase-locked loop feedback clock; and
a controller of the adjustment circuit to adjust the duty cycle of the crystal oscillator clock based on the difference in delay.

17. The system as in claim 16, wherein the detection circuit is to:
shut off an edge of the doubled crystal oscillator clock; and
measure a delay between a non-shut-off edge of the doubled crystal oscillator clock and the phase-locked loop feedback clock.

18. The system as in claim 16,
wherein the detection circuit is to:
measure a first delay between a rising edge of the doubled crystal oscillator clock and the phase-locked loop feedback clock;
measure a second delay between a falling edge of the doubled crystal oscillator clock and the phase-locked loop feedback clock; and
determine an inferred duty cycle of the crystal oscillator clock from a difference between the first delay and the second delay;
wherein the controller is to:
adjust the first stage of the clock circuit to make a first adjustment based on the inferred duty cycle; and
adjust the second stage of the clock circuit to make a second adjustment based on the inferred duty cycle,
wherein the first adjustment is larger than the second adjustment.

19. The system as in claim 16, wherein the controller is to adjust the first stage of the clock circuit by programming a strength of a crystal driver amplifier by independently enabling or disabling P-channel and N-channel devices of a plurality of amplifier stages, wherein more enabled N-channel devices than P-channel devices lowers a threshold of a first stage amplifier, and wherein more enabled P-channel devices than N-channel devices raises a threshold of the first stage amplifier.

20. The system as in claim 16, wherein the controller is to adjust the duty cycle of the crystal oscillator clock by adjusting the second stage of the clock circuit by:
independently enabling sections of a Schmitt trigger amplifier to adjust a low-to-high input threshold of the duty cycle; and
independently enabling sections of a Schmitt trigger attenuator to adjust a high-to-low input threshold of the duty cycle.
